(19) United States
(12) Patent Application Publication
(10) Pub. No.: US 2024/0011157 A1
(43) Pub. Date: Jan. 11, 2024

(54) DEPOSITION APPARATUS

(71) Applicant: NATIONAL CHENG KUNG UNIVERSITY, TAINAN CITY (TW)

(72) Inventors: Yu Chi CHANG, Tainan City (TW); Zhao-Cheng CHEN, Kaohsiung City (TW)

(21) Appl. No.: 18/173,763

(22) Filed: Feb. 23, 2023

(30) Foreign Application Priority Data
Jul. 7, 2022 (TW) 111125499

(51) Int. Cl. C23C 16/455

(52) U.S. Cl. CPC C23C 16/45574; C23C 16/45534; C23C 16/45536

(57) ABSTRACT

A deposition apparatus includes a chamber, a susceptor, several injection pipes, and a plasma device. The susceptor is disposed within the chamber and is configured to carry a substrate. The injection pipes are respectively disposed in and pass through an upper portion of the chamber and are located over the susceptor. A nozzle of each of the injection pipes is tangent to an inner side surface of the chamber, so that several process gases ejected through the nozzles of the injection pipes respectively rotate along the inner side surface of the chamber. The process gases at least include a precursor gas. The plasma device is disposed in and passes through a top of the chamber, and is configured to generate plasma within the chamber to activate the precursor gas to form activators.

### RELATED APPLICATIONS

This application claims priority to Taiwan Application Serial Number 111125499, filed Jul. 7, 2022, which is herein incorporated by reference.

### BACKGROUND

### Field of Invention

The present invention relates to a deposition technology, and more particularly, to a plasma-enhanced deposition apparatus.

### Description of Related Art

Most of current atomic layer deposition apparatuses adopt precursor injection pipes with a single-pipe design or a double-pipe design. In the single-pipe design, when a precursor is injected into a chamber through a single pipe, a gas flow in a gas inlet is relatively large, such that a flow field gas distribution in the chamber is not uniform, resulting in an uneven thickness of the deposited layer. Furthermore, in addition to the gas intake volume, the influence of the gas exhaust volume has to be considered. Most of the parameters make it difficult to balance the gas field inside the chamber, such that the process is extremely unstable. In addition, the atomic layer deposition process usually needs to introduce various precursors, and the precursors may react with each other in the pipe because they use the same flow channel. The reacting of the precursors may produce dust in the pipe. The dust in the pipe not only causes pollution to seriously affect the deposition quality, but also reduces the inner diameter of the pipe, which decreases the injection speed of the precursor, and even causes the pipe to be blocked and unable to introduce the gas.

Although the gas intake method with two pipes can greatly improve the instability of the process gas field in the chamber, an upper portion of a chamber of a typical plasma-enhanced atomic layer deposition (PEALD) apparatus is mostly occupied by an inductively coupled plasma (ICP) module, resulting in a limited space for precursor pipes. Since the precursor pipe needs to be heated and kept warm, it is necessary to install a heating device or an insulating jacket on the precursor pipe, such that the overall outer diameter of the two precursor pipe structures is greatly increased, and the upper portion of the chamber of the plasma-enhanced atomic layer deposition apparatus is more congested. Accordingly, when the apparatus needs to be repaired, disassembled, or installed with other modules or accessories, various inconveniences are caused due to the small space.

### SUMMARY

Therefore, one objective of the present disclosure is to provide a deposition apparatus, in which a nozzle of an injection pipe is tangent to an inner side surface of a chamber, such that a process gas ejected through the nozzle of the injection pipe can rotate along the inner side surface of the chamber in a tangential direction to form a random annular cyclone in the chamber. The process gas is injected into the chamber in the form of a cyclone, and uniformly advances to a coating area in a random distribution, such that it can overcome the problem of excessive difference in process gas concentration in the chamber when the process gas is introduced from one single-point, and eliminate the unevenness of the flow field caused by the gas intake at a specific position in the prior art, thereby enhancing the uniformity of the process.

Another objective of the present disclosure is to provide a deposition apparatus, which can accommodate more process gas injection pipes based on a diameter of an upper portion of the chamber, so different precursors can be injected into the chamber independently through different injection pipes, thereby preventing the different precursors from reacting in the injection pipes to generate dust and plug the pipes.

Still another objective of the present disclosure is to provide a deposition apparatus, in which process gases in the chamber have high uniformity, such that the apparatus with a larger deposition area can be realized, which can increase the throughput.

Further another objective of the present disclosure is to provide a deposition apparatus, which injects process gases tangentially, and the nozzles of the injection pipes do not directly face the substrate to be coated, such that the controllability of the process can be increased, and the adjustable process window is larger.

According to the above objectives, the present disclosure provides a deposition apparatus. The deposition apparatus includes a chamber, a susceptor, several injection pipes, and a plasma device. The susceptor is disposed within the chamber and is configured to carry a substrate. The injection pipes are respectively disposed in and pass through an upper portion of the chamber and are located over the susceptor. A nozzle of each of the injection pipes is tangent to an inner side surface of the chamber, so that several process gases ejected through the nozzles of the injection pipes respectively rotate along the inner side surface of the chamber. The process gases at least include a precursor gas. The plasma device is disposed in and passes through a top of the chamber, and is configured to generate plasma within the chamber to activate the precursor gas to form an activator.

According to one embodiment of the present disclosure, the injection pipes surround the upper portion of the chamber at a constant pitch.

According to one embodiment of the present disclosure, the process gases further include another precursor gas, and after the another precursor gas is attached to the substrate, the activator attaches to the another precursor gas and reacts with the another precursor gas.

According to one embodiment of the present disclosure, the plasma device includes an inductively coupled plasma (ICP) device.

According to one embodiment of the present disclosure, the process gases include a diluent gas.

According to one embodiment of the present disclosure, the process gases comprise a purge gas.

According to one embodiment of the present disclosure, a number of the injection pipes is six, two of the injection pipes are two precursor injection pipes, another two of the injection pipes are two purge gas injection pipes, and the other two of the injection pipes are two diluent gas injection pipes.

According to one embodiment of the present disclosure, the two precursor injection pipes are arranged opposite to each other, one of the two purge gas injection pipes and one of the two diluent gas injection pipes are located at one side of the two precursor injection pipes and between the two precursor injection pipes, and the other one of the two purge gas injection pipes and the other one of the two diluent gas injection pipes are arranged on an opposite side of the side of the two precursor injection pipes and between the two precursor injection pipes.

According to one embodiment of the present disclosure, a number of the injection pipes is eight, six of the injection pipes are divided into two precursor injection pipe groups, each of the two precursor injection pipe groups includes three precursor injection pipes, the other two of the injection pipes are two diluent gas injection pipes, and the two diluent gas injection pipes are respectively located between the two precursor injection pipe groups.

According to one embodiment of the present disclosure, the deposition apparatus is a plasma-enhanced atomic layer deposition (PEALD) apparatus.

### BRIEF DESCRIPTION OF THE DRAWINGS

In order to make the above and other objectives, features, advantages, and embodiments of the present disclosure more comprehensible, the accompanying drawings are described as follows:

FIG. 1 is a schematic diagram of a deposition apparatus according to one embodiment of the present disclosure;

FIG. 2 is a schematic diagram showing an arrangement of injection pipes on a chamber according to one embodiment of the present disclosure;

FIG. 3 is a schematic diagram showing another arrangement of injection pipes on a chamber according to one embodiment of the present disclosure; and

FIG. 4 is a schematic diagram showing another arrangement of injection pipes on a chamber according to one embodiment of the present disclosure.

### DETAILED DESCRIPTION

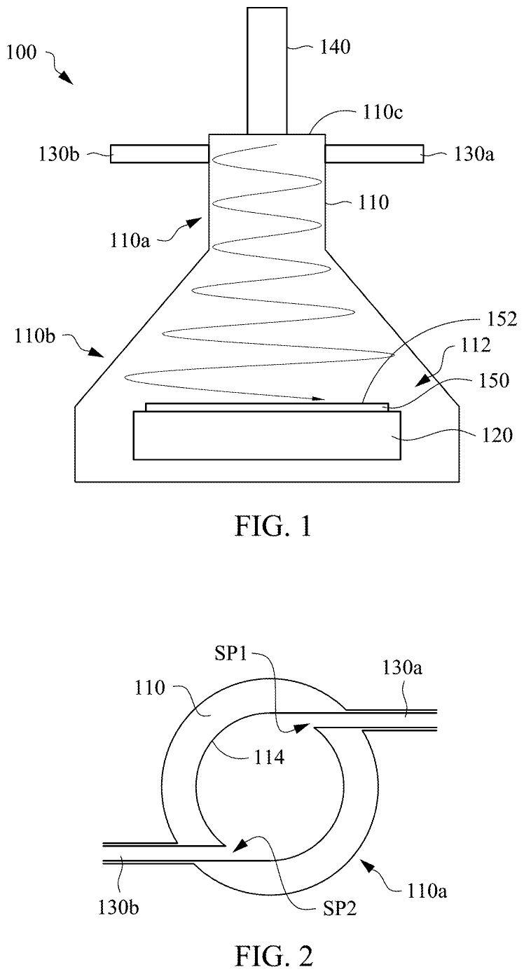

Referring to FIG. 1 and FIG. 2, FIG. 1 is a schematic diagram of a deposition apparatus according to one embodiment of the present disclosure, and FIG. 2 is a schematic diagram showing an arrangement of injection pipes on a chamber according to one embodiment of the present disclosure. A deposition apparatus 100 is a plasma-enhanced deposition apparatus. For example, the deposition apparatus 100 may be a plasma-enhanced atomic layer deposition apparatus. The deposition apparatus 100 may mainly include a chamber 110, a susceptor 120, several injection pipes 130a and 130b, and a plasma device 140.

The chamber 110 has an inner space 112, and a deposition reaction can be performed in the inner space. The chamber 110 of suitable shape and size can be selected according to the field space where the apparatus is located and the process requirements. In the example shown in FIG. 1, the chamber 110 includes an upper portion 110a and a lower portion 110b, in which the upper portion 110a is located above the lower portion 110b, and the upper portion 110a and the lower portion 110b are connected to each other to collectively define the inner space 112. In some exemplary examples, the upper portion 110a may be an inverted barrel-shaped structure, such as a drum-shaped structure. An inner diameter of the lower portion 110b may gradually increase downwards from the upper portion 110a, and when the inner diameter of the lower portion 110b increases to a certain extent, the inner diameter of the lower portion 110b is maintained at a constant value. The lower portion 110b may be, for example, an inverted funnel-shaped structure. The changes in the shape and the inner diameter of the chamber 110 are only for illustration, and the embodiment is not limited thereto.

The susceptor 120 is disposed within the inner space 112 of the chamber 110. For example, the susceptor 120 is disposed in the lower portion 110b of the chamber 110. The susceptor 120 is configured to carry a substrate 150. The substrate 150 may be, for example, a workpiece to be coated. The susceptor 120 may include a holding device, such as a vacuum suction device or a clamping device, to stably carry the substrate 150 during the deposition process.

In the example shown in FIG. 1 and FIG. 2, the deposition apparatus 100 includes two injection pipes 130a and 130b. However, in other examples, the deposition apparatus 100 may include more than two injection pipes. The injection pipes 130a and 130b are respectively disposed in and pass through the upper portion 110a of the chamber 110, such that the injection pipes 130a and 130b are located above the susceptor 120, which is disposed in the lower portion 110b. Each of the injection pipes 130a and 130b may respectively supply a kind of process gas into the inner space 112 of the chamber 110. Therefore, different process gases can be independently injected into the chamber 110 through the injection pipes 130a and 130b, thereby avoiding dust pollution or pipe plugging problems caused by the different process gases sharing the same pipe. At least one of the two process gases is a precursor gas. The precursor gas may also include a carrier gas for carrying the precursor. In some examples, the two process gases may be different precursor gases. In other examples, one of the two process gases is a precursor gas, and the other one may be a related process gas, such as a dilute gas or a purge gas.

The positions of the injection pipes 130a and 130b may be arranged according to the process requirements. The injection pipes 130a and 130b may be arranged opposite to each other on the upper portion 110a of the chamber 110, for example. However, the injection pipes 130a and 130b may have different arrangements. As shown in FIG. 2, a nozzle SP1 of the injection pipe 130a and a nozzle SP2 of the injection pipe 130b are all tangent to an inner side surface 114 of the chamber 110. With the design, the process gases ejected through the nozzle SP1 of the injection pipe 130a and the nozzle SP2 of the injection pipe 130b can be injected into the chamber 110 in a tangential direction, and rotate downstream along the inner side surface 114 of the chamber 110 in the limited tubular space of the upper portion 110a to form process gas cyclones. Since the process gases are injected into the chamber 110 in a rotating manner, annular random cyclones are formed, such that the gases can randomly fill the inner space 112 of the chamber 110. Accordingly, the uneven flow field caused by the gas intake at a specific position can be eliminated, and the technical problems of conventional deposition apparatus, such as gas intake eccentricity, space, independent parameters, and too small process window can be effectively solved. Therefore, in a certain example that the deposition apparatus includes one single injection pipe, the uneven flow field caused by the gas intake at a specific location can also be eliminated, but the single injection pipe is more prone to dust or plugging problems.

In addition, the process gases are injected tangentially through the injection pipes 130a and 130b, such that the nozzle SP1 of the injection pipe 130a and the nozzle SP2 of the injection pipe 130b do not directly face the substrate 150, thereby effectively enhancing the control of the process, and broadening the process window. Furthermore, the injection pipes 130a and 130b are obliquely arranged in the side wall of the upper portion 110a of the chamber 110, so that the respective nozzles SP1 and SP2 are tangent to the inner side surface 114 of the chamber 110. Such an arrangement can have more space for setting heating modules of the injection pipes 130a and 130b.

The plasma device 140 is disposed in and passes through a top 110c of the chamber 110. Therefore, the plasma device is located above the injection pipes 130a and 130b and the susceptor 120. In some exemplary examples, the plasma device 140 is an inductively coupled plasma device. The plasma device 140 can also choose different types of plasma devices according to the process requirements, and the present embodiment is not limited to the inductively coupled plasma device. The plasma device 140 can generate plasma in the inner space 112 of the chamber 110. The active species in the plasma can activate the precursor gas injected into the chamber 110 through the injection pipes 130a and/or 130b to form an activator.

In some examples, another precursor gas may be injected into the inner space 112 of the chamber 110 through one of the injection pipes 130a and 130b first, such that the another precursor gas can be uniformly deposited on a surface 152 of the substrate 150 in a random cyclone manner. Subsequently, the precursor gas is injected into the inner space 112 of the chamber 110 in a tangential rotational manner through one of the injection pipes 130a and 130b, and the precursor gas is activated by the energy of the plasma to form an activator. The activator can evenly fall on the another precursor gas on the surface 152 of the substrate 150 because the activator moves downstream in a random cyclone, and the activator reacts and bonds with the another precursor gas to form a deposited layer of a uniform thickness on the surface 152 of the substrate 150.

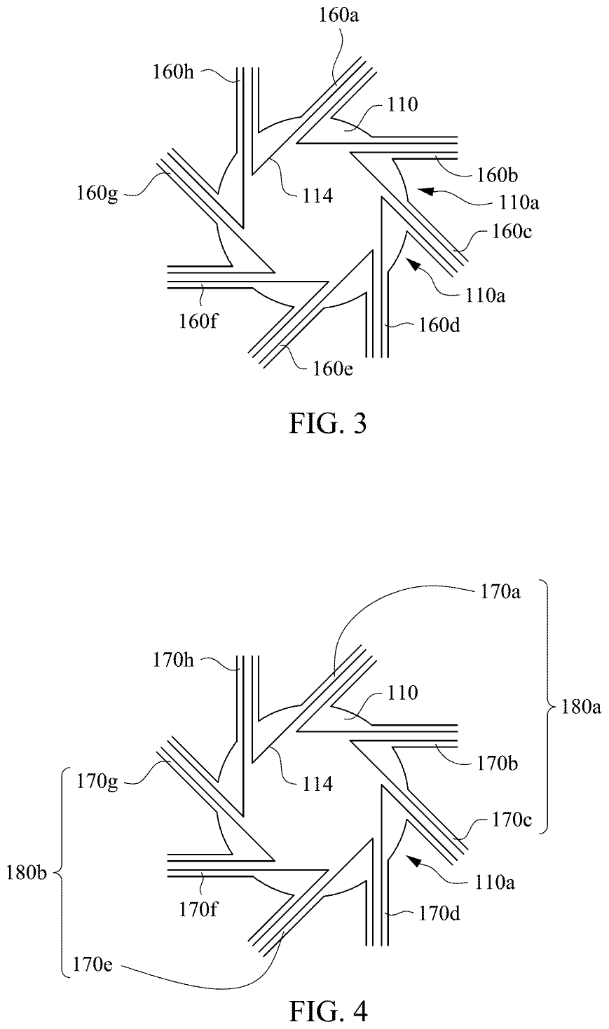

The deposition apparatus of the present disclosure can be equipped with more injection pipes. Referring to FIG. 3, FIG. 3 is a schematic diagram showing another arrangement of injection pipes on a chamber according to one embodiment of the present disclosure. The embodiment installs more than two injection pipes on the chamber 110. In some examples, six injection pipes 160a, 160b, 160c, 160e, 160f, and 160g are disposed on the chamber 110. Among the injection pipes 160a, 160b, 160c, 160e, 160f, and 160g, two injection pipes 160a and 160e may be respectively precursor injection pipes, another two injection pipes 160c and 160g may be respectively purge gas injection pipes, and the other two injection pipes 160b and 160f may be two dilution gas injection pipes respectively. The injection pipes 160a and 160e can be used for injecting different precursors into the chamber 110 respectively, or for injecting the same precursor into the chamber 110. The injection pipes 160c and 160g can be used for injecting a purge gas into the chamber 110. The injection pipes 160b and 160f can be used for injecting a diluent gas into the chamber 110.

In such an example, starting from the injection pipe 160a, along a clockwise direction, the injection pipe 160b for a dilute gas is immediately behind the injection pipe 160a for a precursor, the injection pipe 160c for a purge gas is located behind the injection pipe 160b, the injection pipe 160e for another precursor is located behind the injection pipe 160c, the injection pipe 160f for another dilute gas is located behind the injection pipe 160e, and the injection pipe 160g for another purge gas is located behind the injection pipe 160f. Accordingly, two injection pipes 160a and 160e for the precursors may be arranged opposite to each other, and the injection pipe 160c for the purge gas and the injection pipe 160b for the dilute gas are arranged at one side, such as a right side, of the injection pipes 160a and 160e for the precursors and are located between the injection pipes 160a and 160e. The other injection pipe 160g for the purge gas and the other injection pipe 160f for the diluent gas are disposed on the opposite side, such as the left side, of the side of the injection pipes 160a and 160e and between the injection pipes 160a and 160e.

In other examples, two spare injection pipes 160d and 160h may be optionally provided for possible injection needs. The two spare injection pipes 160d and 160h are respectively located between the injection pipe 160c for the purge gas and the injection pipe 160e for the precursor, and between the injection pipe 160g for the purge gas and the injection pipe 160a for the precursor. In some exemplary examples, the injection pipes 160a to 160h surround the upper portion 110a of the chamber 110 at a constant pitch. Certainly, the injection pipes 160a to 160h may be arranged on the upper portion 110a of the chamber 110 at inconstant pitches. In addition, the nozzles of the injection pipes 160a to 160h are all tangent to the inner side surface 114 of the chamber 110.

Referring FIG. 4, FIG. 4 is a schematic diagram showing another arrangement of injection pipes on a chamber according to one embodiment of the present disclosure. Eight injection pipes 170a, 170b, 170c, 170d, 170e, 170f, 170g, and 170h are disposed on the chamber 110. In some exemplary examples, six of the injection pipes 170a to 170h are divided into two precursor injection pipe groups 180a and 180b. Each of the precursor injection pipe groups 180a and 180b includes three precursor injection pipes, in which the precursor injection pipe group 180a includes injection pipes 170a, 170b, and 170c, and the precursor injection pipe group 180b includes injection pipes 170e, 170f, and 170g. The other two injection pipes 170d and 170h of the injection pipes 170a to 170h are dilute gas injection pipes.

The injection pipes 170a to 170c and the injection pipes 170e to 170g may be used for injecting six different precursors into the chamber 110, and may also be used for injecting the same precursor into the chamber. Alternatively, among the six precursors injected into the chamber 110 from the injection pipes 170a to 170c and the injection pipes 170e to 170g, some of the precursors are the same, while some of the precursors are different. For example, the injection pipes 170a and 170e may be used to inject the same precursor, the injection pipes 170b and 170f may be used to inject another precursor, and the injection pipes 170c and 170g may be used to inject the other precursor, in which these three precursors are different from each other. The kinds of precursors injected into the chamber 110 through the injection pipes 170a to 170c and the injection pipes 170e to 170g can be adjusted according to the process requirements, and the present disclosure is not limited thereto.

In such an example, starting from the injection pipe 170a, along a clockwise direction, the injection pipe 170b for one precursor is behind the injection pipe 170a for one precursor, the injection pipe 170c for one precursor is behind the injection pipe 170b, the injection pipe 170d for one dilute gas is behind the injection pipe 170c, the injection pipe 170e for one precursor in the other group is disposed behind the injection pipe 170d, the injection pipe 170f for one precursor is behind the injection pipe 170e, the injection pipe 170g for one precursor is behind the injection pipe 170f, and the injection pipe 170h for one dilute gas is behind the injection pipe 170g. Therefore, the two injection pipes 170d and 170h for the dilute gases may be respectively located between the two precursor injection pipe groups 180a and 180b.

The nozzles of the injection pipes 170a to 170h are all tangent to the inner side surface 114 of the chamber 110. In some exemplary examples, the injection pipes 170a to 170h surround the upper portion 110a of the chamber 110 at a constant pitch. However, the injection pipes 170a to 170h may also be arranged on the upper portion 110a of the chamber 110 at inconstant pitches.

The number, arrangement, and functions of the injection pipes in the above embodiments are only for illustration, and the number, arrangement, and functions of the injection pipes can be adjusted according to the process requirements, and the present disclosure is not limited thereto.

According to the aforementioned embodiments, one advantage of the present disclosure is that a nozzle of an injection pipe of the deposition apparatus of the present disclosure is tangent to an inner side surface of a chamber, such that a process gas ejected through the nozzle of the injection pipe can rotate along the inner side surface of the chamber in a tangential direction to form a random annular cyclone in the chamber. The process gas is injected into the chamber in the form of a cyclone, and uniformly advances to a coating area in a random distribution, such that it can overcome the problem of excessive difference in process gas concentration in the chamber when the process gas is introduced from one single-point, and eliminate the unevenness of the flow field caused by the gas intake at a specific position in the prior art, thereby enhancing the uniformity of the process.

Another advantage of the present disclosure is that the deposition apparatus of the present disclosure can accommodate more process gas injection pipes based on a diameter of an upper portion of the chamber, so different precursors can be injected into the chamber independently through different injection pipes, thereby preventing the different precursors from reacting in the injection pipes to generate dust and plug the pipes.

Still another advantage of the present disclosure is that with the applying of the deposition apparatus of the present disclosure, the process gases in the chamber have high uniformity, such that the apparatus with a larger deposition area can be realized, which can increase the throughput.

Further another advantage of the present disclosure is that a deposition apparatus of the present disclosure injects process gases tangentially, and the nozzles of the injection pipes do not directly face the substrate to be coated, such that the controllability of the process can be increased, and the adjustable process window is larger.

Although the present disclosure has been disclosed above with embodiments, it is not intended to limit the present disclosure. Any person having ordinary skill in the art can make various changes and modifications without departing from the spirit and scope of the present disclosure. Therefore, the protection scope of the present disclosure should be defined by the scope of the appended claims.

What is claimed is:

1. A deposition apparatus, comprising:
a chamber;
a susceptor disposed within the chamber and configured to carry a substrate;
a plurality of injection pipes respectively disposed in and passing through an upper portion of the chamber and located over the susceptor, wherein a nozzle of each of the injection pipes is tangent to an inner side surface of the chamber, so that a plurality of process gases ejected through the nozzles of the injection pipes respectively rotate along the inner side surface of the chamber, and wherein the process gases at least comprise a precursor gas; and
a plasma device disposed in and passing through a top of the chamber, and configured to generate plasma within the chamber to activate the precursor gas to form an activator.

2. The deposition apparatus of claim 1, wherein the injection pipes surround the upper portion of the chamber at a constant pitch.

3. The deposition apparatus of claim 1, wherein the process gases further comprise another precursor gas, and after the another precursor gas is attached to the substrate, the activator attaches to the another precursor gas and reacts with the another precursor gas.

4. The deposition apparatus of claim 1, wherein the plasma device comprises an inductively coupled plasma device.

5. The deposition apparatus of claim 1, wherein the process gases comprise a diluent gas.

6. The deposition apparatus of claim 1, wherein the process gases comprise a purge gas.

7. The deposition apparatus of claim 1, wherein a number of the injection pipes is six, two of the injection pipes are two precursor injection pipes, another two of the injection pipes are two purge gas injection pipes, and the other two of the injection pipes are two diluent gas injection pipes.

8. The deposition apparatus of claim 7, wherein the two precursor injection pipes are arranged opposite to each other, one of the two purge gas injection pipes and one of the two diluent gas injection pipes are located at one side of the two precursor injection pipes and between the two precursor injection pipes, and the other one of the two purge gas injection pipes and the other one of the two diluent gas injection pipes are arranged on an opposite side of the side of the two precursor injection pipes and between the two precursor injection pipes.

9. The deposition apparatus of claim 1, wherein a number of the injection pipes is eight, six of the injection pipes are divided into two precursor injection pipe groups, each of the two precursor injection pipe groups comprises three precursor injection pipes, the other two of the injection pipes are two diluent gas injection pipes, and the two diluent gas injection pipes are respectively located between the two precursor injection pipe groups.

10. The deposition apparatus of claim 1, wherein the deposition apparatus is a plasma-enhanced atomic layer deposition apparatus.

11. A deposition apparatus, comprising:
a chamber comprising an upper portion and a lower portion, wherein the upper portion is connected to a top of the lower portion, and the upper portion is an inverted drum-shaped structure;
a susceptor disposed within the lower portion and configured to carry a substrate;
a plurality of injection pipes respectively disposed in and passing through the upper portion and located over the susceptor, wherein a nozzle of each of the injection pipes is tangent to an inner side surface of the chamber, so that a plurality of process gases ejected through the nozzles of the injection pipes respectively rotate along the inner side surface of the chamber, and wherein the process gases at least comprise a precursor gas; and
a plasma device disposed in and passing through a top of the chamber, and configured to generate plasma within the chamber to activate the precursor gas to form an activator.

12. The deposition apparatus of claim 11, wherein an inner diameter of the lower portion gradually increases downwards from the upper portion to a predetermined value.

13. The deposition apparatus of claim 11, wherein the lower portion is an inverted funnel-shaped structure.

14. The deposition apparatus of claim 11, wherein the injection pipes surround the upper portion of the chamber at a constant pitch.

15. The deposition apparatus of claim 11, wherein the process gases further comprise another precursor gas, and after the another precursor gas is attached to the substrate, the activator attaches to the another precursor gas and reacts with the another precursor gas.

16. The deposition apparatus of claim 11, wherein the plasma device comprises an inductively coupled plasma device.

17. The deposition apparatus of claim 11, wherein a number of the injection pipes is six, two of the injection pipes are two precursor injection pipes, another two of the injection pipes are two purge gas injection pipes, and the other two of the injection pipes are two diluent gas injection pipes.

18. The deposition apparatus of claim 17, wherein the two precursor injection pipes are arranged opposite to each other, one of the two purge gas injection pipes and one of the two diluent gas injection pipes are located at one side of the two precursor injection pipes and between the two precursor injection pipes, and the other one of the two purge gas injection pipes and the other one of the two diluent gas injection pipes are arranged on an opposite side of the side of the two precursor injection pipes and between the two precursor injection pipes.

19. The deposition apparatus of claim 11, wherein a number of the injection pipes is eight, six of the injection pipes are divided into two precursor injection pipe groups, each of the two precursor injection pipe groups comprises three precursor injection pipes, the other two of the injection pipes are two diluent gas injection pipes, and the two diluent gas injection pipes are respectively located between the two precursor injection pipe groups.

20. The deposition apparatus of claim 11, wherein the deposition apparatus is a plasma-enhanced atomic layer deposition apparatus.
